(19) United States
(12) Patent Application Publication
(10) Pub. No.: US 2024/0016063 A1
(43) Pub. Date: Jan. 11, 2024

(54) MRAM STRUCTURE AND METHOD OF FABRICATING THE SAME

(71) Applicant: UNITED MICROELECTRONICS CORP., Hsin-Chu City (TW)

(72) Inventors: Chih-Wei Kuo, Tainan City (TW); Chung-Yi Chiu, Tainan City (TW); Shun-Yu Huang, Kaohsiung City (TW); Yi-Wei Tseng, New Taipei City (TW)

(73) Assignee: UNITED MICROELECTRONICS CORP., Hsin-Chu City (TW)

(21) Appl. No.: 17/884,528

(22) Filed: Aug. 9, 2022

(30) Foreign Application Priority Data
Jul. 8, 2022 (TW) 111125724

(51) Int. Cl. H01L 43/08; H01L 27/22; H01L 43/02; H01L 43/12

(52) U.S. Cl. CPC H01L 43/08; H01L 27/222; H01L 43/02; H01L 43/12

(57) ABSTRACT

An MRAM structure includes an MTJ, a first SOT element, a conductive layer and a second SOT element disposed from bottom to top. A protective layer is disposed on the second SOT element. The protective layer covers and contacts a top surface of the second SOT element. The protective layer is an insulator. A conductive via penetrates the protective layer and contacts the second SOT element.

### BACKGROUND OF THE INVENTION

### 1. Field of the Invention

The present invention relates to a magnetoresistive random access memory (MRAM) structure and a fabricating method of the same, and more particularly to an MRAM structure which has a protective layer formed on a spin orbit torque (SOT) element and a fabricating method of the same.

### 2. Description of the Prior Art

Many modern day electronic devices contain electronic memory configured to store data. Electronic memory may be volatile memory or non-volatile memory. Volatile memory stores data only while it is powered, while non-volatile memory is able to store data even when power is removed. MRAM is one promising candidate for next generation non-volatile memory technology. An MRAM cell includes a magnetic tunnel junction (MTJ) having a variable resistance, located between two electrodes disposed within back-end-of-the-line (BEOL) metallization layers.

An MTJ generally includes a layered structure comprising a pinned layer, a free layer and a tunnel oxide in between. The pinned layer of magnetic material has a magnetic moment that always points in the same direction. The magnetic moment of the free layer is free, but is determined by the physical dimensions of the element. The magnetic moment of the free layer points in either of two directions: parallel or anti-parallel with the magnetization direction of the pinned layer.

However, conventional fabricating processes of MRAM still need to be improved. For example, conductive layers are oxidized or a surface of material layer is damaged during the fabricating process.

### SUMMARY OF THE INVENTION

In view of this, the present invention provides an MRAM structure with a protective layer covering an SOT element to solved above-mentioned problem.

According to a preferred embodiment of the present invention, an MRAM structure includes an MTJ, a first SOT element, a conductive layer and a second SOT element disposed from bottom to top. A protective layer is disposed on the second SOT element, wherein the protective layer covers and contacts a top surface of the second SOT element, and the protective layer is an insulator. A first conductive via penetrates the protective layer and contacts the second SOT element.

According to another preferred embodiment of the present invention, a fabricating method of an MRAM structure, includes providing a first dielectric layer, wherein a first memory structure and a second memory structure are disposed within the first dielectric layer, a spacer material layer is disposed at a sidewall of the first memory structure and extends to a sidewall of the second memory structure. Next, an SOT material layer and a protective material layer are formed in sequence to cover the first memory structure and the second memory structure, wherein the SOT material layer contacts the first memory structure and the second memory structure, the protective material layer contacts the SOT material layer. After that, a trench is formed within the first dielectric layer, wherein the trench segments the SOT material layer, the protective material layer and the spacer material layer to divide the SOT material layer into a first SOT element and a second SOT element, and to divide the protective material layer into a first protective layer and a second protective layer. After that, a second dielectric layer is formed to fill in the trench, wherein a top surface of the second dielectric layer is aligned with a top surface of the first protective layer. Finally, a first conductive via and a second conductive via are formed, wherein the first conductive via penetrates the first protective layer and contacts the first SOT element, the second conductive via penetrates the second protective layer and contacts the second SOT element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 depict an MRAM structure and a fabricating method of the MRAM structure according to a preferred embodiment of the present invention, wherein:

FIG. 1 shows a fabricating stage of two memory structures;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4;

FIG. 6 is a fabricating stage in continuous of FIG. 5; and

FIG. 7 is a fabricating stage in continuous of FIG. 6.

FIG. 8 depicts a sectional view of the MRAM at the left side taking alone a direction perpendicular to a plane of paper along the inward direction.

FIG. 9 to FIG. 10 depict a fabricating method of an MRAM structure according to an example of the present invention, wherein:

FIG. 9 shows a fabricating stage of two memory structures with oxide layers thereon;

and

FIG. 10 is a fabricating stage in continuous of FIG. 9.

### DETAILED DESCRIPTION

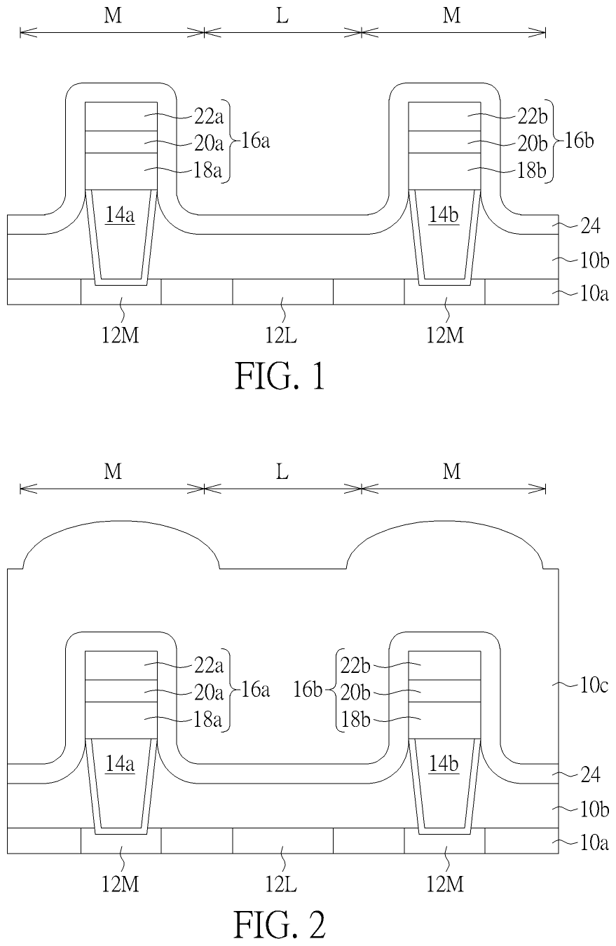

FIG. 1 to FIG. 7 depict an MRAM structure and a fabricating method of the MRAM structure according to a preferred embodiment of the present invention.

As shown in FIG. 1, a dielectric layer 10a is provided. Two metal lines 12M are embedded into a memory region M of the dielectric layer 10a. A metal line 12L is embedded in a logic circuit region L of the dielectric layer 10a. The metal lines 12M and the metal line 12L can be made of Cu, Al, W or other conductive materials. A dielectric layer 10b covers the dielectric layer 10a. Two conductive vias 14a/14b are embedded in the dielectric layer 10b and the conductive vias 14a/14b respectively contact different metal lines 12M. A first memory structure 16a is disposed on the conductive via 14a and contacts the conductive via 14a. A second memory structure 16b is disposed on the conductive via 14b and contacts the conductive via 14b. A first memory structure 16a includes a first magnetic tunnel junction (MTJ) 18a, a third spin orbit torque (SOT) element 20a, and a first conductive layer 22a disposed from bottom to top. A second memory structure 16b includes a second MTJ 18b, a fourth SOT element 20b, and a second conductive layer 22b disposed from bottom to top. A spacer material layer 24 conformally covers the dielectric layer 10b, the first memory structure 16a and the second memory structure 16b. In details, the spacer material layer 24 covers a sidewall of the first memory structure 16a and extends to a sidewall of the second memory structure 16b. The dielectric layers 10a/10b include silicon oxide. The first MTJ 18a and the second MTJ 18b respectively include two magnetic films and an oxide layer sandwiched between the two magnetic films. The oxide layer may be magnesium oxide. One of the magnetic films is a pinned layer, and the other one of the magnetic films is a free layer. The third SOT element 20a and the fourth SOT element 20b are used to change the torque direction of the free layer. The third SOT element 20a and the fourth SOT can respectively include W, Pt, Ta, or TiN. The first conductive layer 22a and the second conductive layer 22b may respectively include Ta, Pt, or WN.

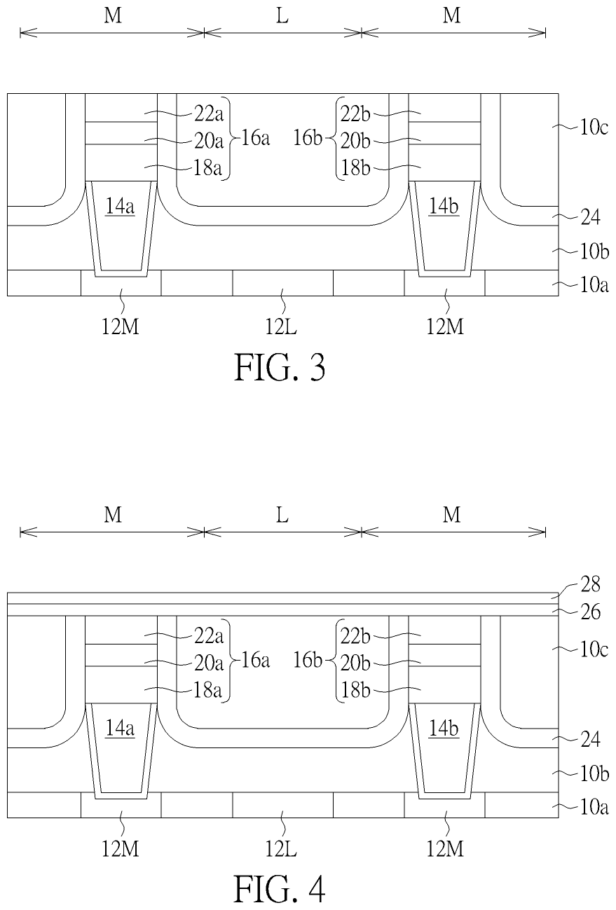

As shown in FIG. 2, a dielectric layer 10c is formed to cover the spacer material layer 24. The dielectric layer 10c is preferably silicon oxide. The silicon oxide can be formed by a chemical vapor deposition, a physical vapor deposition, or an atomic layer deposition. At this point, the first memory structure 16a and the second memory structure 16b are disposed within the dielectric layer 10c. As shown in FIG. 3, a planarization process such as a chemical mechanical polishing process is performed to remove part of the dielectric layer 10c by taking the spacer material layer 24 as an etching stop layer. Now, the spacer material layer 24 still covers the top surface of the first memory structure 16a and the top surface of the second memory structure 16b. Next, the spacer material layer 24 on the top surface of the first memory structure 16a and on the top surface of the second memory structure 16b are removed to expose the top surface of the first memory structure 16a and the top surface of the second memory structure 16b. The spacer material layer 24 may include silicon oxide or silicon nitride.

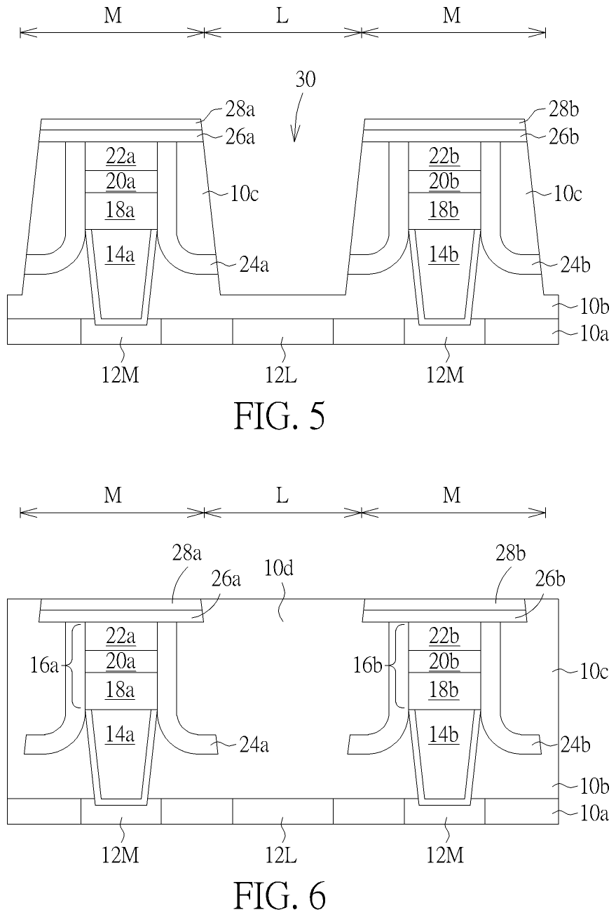

As shown in FIG. 4, an SOT material layer 26 is formed to cover the first memory structure 16a and the second memory structure 16b. Later, a protective material layer 28 is formed to cover and contact the SOT material layer 26. The SOT material layer 26 includes W, Pt, Ta or TiN. The protective material layer 28 includes nitrogen-containing materials such as silicon nitride or carbon-doped silicon nitride (SiCN). As shown in FIG. 5, a trench 34 is formed in the dielectric layers 10c/10b. The trench 30 segments the SOT material layer 26, the protective material layer 28 and the spacer material layer 24 to divide the SOT material layer 26 into a first SOT element 26a and a second SOT element 26b, to divide the protective material layer 28 into a first protective layer 28a and a second protective layer 28b and to divide the spacer material layer 24 into a first spacer 24a and a second spacer 24b. The first SOT element 26a and the first protective layer 28a cover the first memory structure 16a. The first SOT element 26a contacts the first memory structure 16a. The second SOT element 26b and the second protective layer 28b cover the second memory structure 16b. The second SOT element 26b contacts the second memory structure 16b. The first spacer 24a is on the sidewall of the first memory structure 16a. The second spacer 24b is on the sidewall of the second memory structure 16b. The first spacer 24a faces to the second spacer 24b.

As shown in FIG. 6, a dielectric layer 10d fills in the trench 30 and covers the first protective layer 28a and the second protective layer 28b. Next, the dielectric layer 10d is planarized to make the top surface of the dielectric layer 10d, the top surface of the first protective layer 28a and the top surface of the second protective layer 28b align with each other. As shown in FIG. 7, a third conductive via V3 is formed in the dielectric layer 10d. The third conductive via V3 contacts the metal line 12L within the logic circuit region L. Then, an etching stop layer 32 and a dielectric layer 10e are formed to cover the first protective layer 28, the third conductive via V3 and the second protective layer 28b. The etching stop layer 32 may be carbon-doped silicon nitride. The dielectric layer 10e may be silicon oxide. Later, a first conductive via V1, a second conductive via V2 and a fourth conductive via V4 are formed to embedded in the etching stop layer 32 and the dielectric layer 10e. The first conductive via V1 penetrates the first protective layer 28a and contacts the first SOT element 26a. The second conductive via V2 penetrates the second protective layer 28b and contacts the second SOT element 26b. The fourth conductive via V4 contacts the third conductive via V3. Now, an MRAM structure 100 of the present invention is completed.

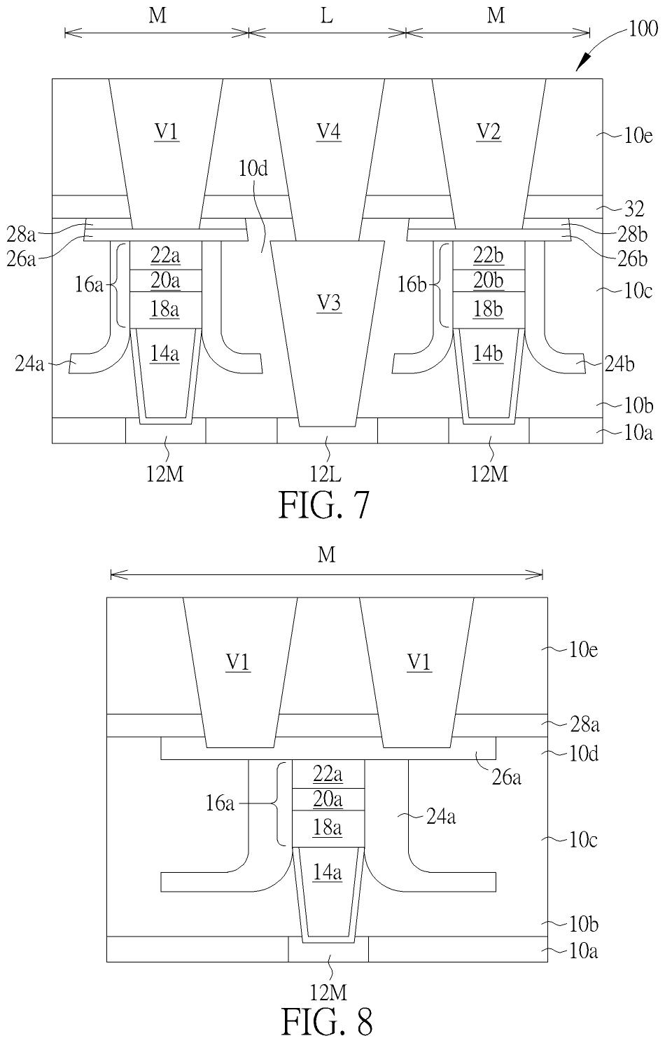

FIG. 8 depicts a sectional view of the MRAM at the left side taking alone a direction perpendicular to a plane of paper along the inward direction. As shown in FIG. 8, the first SOT element 26a connects to two first conductive vias V1. Therefore, current can flow into the first SOT element 26a and pass the third SOT element 20a from one of the two first conductive vias V1 and flow out through the other one of the two first conductive vias V1.

As shown in FIG. 7, an MRAM structure 100 includes a first MTJ 18a, a third SOT element 20a, a first conductive layer 22a and a first SOT element 26a disposed from bottom to top. A first protective layer 28a is disposed on the first SOT element 26a. The first protective layer 28a covers and contacts the top surface of the first SOT element 26a. The first protective layer 28a is an insulator. A first conductive via V1 penetrates the protective layer 28a and contacts the first SOT element 26a. A first spacer 24a contacts the sidewall of the first MTJ 18a, the sidewall of the third SOT element 20a, the sidewall of the first conductive layer 22a. The first spacer 24a is disposed below the first SOT element 26a. Moreover, the conductive via 14a is disposed below the first MTJ 18a and contacts the first MTJ 18a. The width of the first SOT element 26a is greater than the width of the first conductive layer 22a. A dielectric layer 10d surrounds the first protective layer 28a and the first SOT element 26a. The dielectric layer 10d and the first protective layer 28a are made of different materials. The first protective layer 28 includes nitrogen-containing material such as silicon nitride or carbon-doped silicon nitride. In this embodiment, the first protective layer 28a is preferably silicon nitride, and the dielectric layer 10d is preferably silicon oxide.

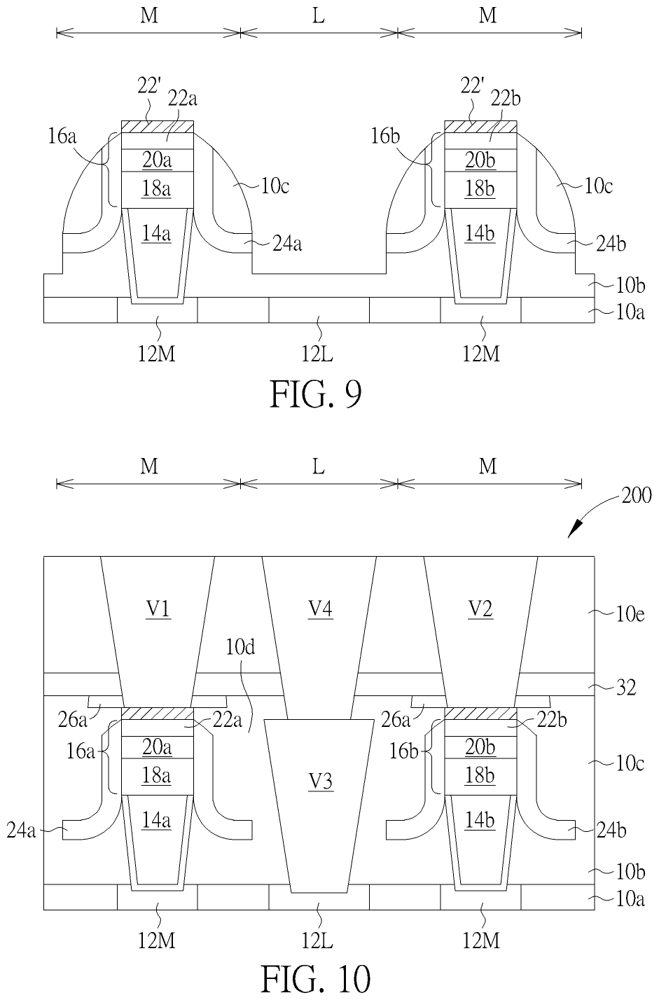

FIG. 9 to FIG. 10 depict a fabricating method of an MRAM structure according to an example of the present invention, wherein elements which are substantially the same as those in the embodiment of FIG. 1 to FIG. 7 are denoted by the same reference numerals; an accompanying explanation is therefore omitted. After the dielectric layer 10c is formed in the stage shown in FIG. 2, as shown in FIG. 9, an etching process is performed to etch back the dielectric layer 10c and the spacer material layer 24 to segment the spacer material layer 24. However during the etching process, the first conductive layer 22a and the second conductive layer 22b are exposed and oxidized to form an oxide layer 22′. As shown in FIG. 10, after the dielectric layer 10d is formed, the SOT material layer 26 is formed to cover the dielectric layer 10d. However, the protective material layer is not formed in this example. Next, the SOT material layer 26 is patterned to form the first SOT element 26a and the second SOT element 26b. Finally, the first conductive via V1 and the second conductive via V2 are respectively formed on the first SOT element 26a and the second SOT element 26b. Because the top surface of the first conductive layer 22a and the top surface of the second conductive layer 22b are oxidized, the resistance of the MRAM structure 200 will be increased. Furthermore, there is no protective layer on the first SOT element 26a and the second SOT element 26b, therefore, the surface of the first SOT element 26a and the second SOT element 26b may be damaged at the following fabricating processes.

On the contrary, the first protective layer 28a and the second protective layer 28b are arranged in the MRAM structure 100 shown in FIG. 7, therefore, the first SOT element 26a and the second SOT element 26b will be protected during following fabricating processes. Moreover, as shown in FIG. 3, the dielectric layer 10c is not etched back, and the spacer material layer 24 serves as the etching stop layer during the planarization process, therefore the top surface of the first conductive layer 22a and the top surface of the second conductive layer 22b will not be oxidized.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetoresistive random access memory (MRAM) structure, comprising:
a magnetic tunnel junction (MTJ), a first spin orbit torque (SOT) element, a conductive layer and
a second SOT element disposed from bottom to top;
a protective layer disposed on the second SOT element, wherein the protective layer covers and
contacts a top surface of the second SOT element, and the protective layer is an insulator; and
a first conductive via penetrating the protective layer and contacting the second SOT element.

2. The MRAM structure of claim 1, further comprising a spacer contacting a sidewall of the MTJ, a sidewall of the first SOT element, a sidewall of the conductive layer, and the spacer being disposed below the second SOT element.

3. The MRAM structure of claim 1, further comprising a second conductive via disposed below the MTJ and contacting the MTJ.

4. The MRAM structure of claim 1, wherein a width of the second SOT element is greater than a width of the conductive layer.

5. The MRAM structure of claim 1, further comprising a dielectric layer surrounding the protective layer and the second SOT element.

6. The MRAM structure of claim 5, wherein a material of the dielectric layer and a material of the protective layer are different.

7. The MRAM structure of claim 1, wherein the protective layer comprises a nitrogen-containing material.

8. A fabricating method of a magnetoresistive random access memory (MRAM) structure, comprising:
providing a first dielectric layer, wherein a first memory structure and a second memory structure are disposed within the first dielectric layer, a spacer material layer is disposed at a sidewall of the first memory structure and extends to a sidewall of the second memory structure;
forming a spin orbit torque (SOT) material layer and a protective material layer in sequence to cover the first memory structure and the second memory structure, wherein the SOT material layer contacts the first memory structure and the second memory structure, the protective material layer contacts the SOT material layer;
forming a trench within the first dielectric layer, wherein the trench segments the SOT material layer, the protective material layer and the spacer material layer to divide the SOT material layer into a first SOT element and a second SOT element, and to divide the protective material layer into a first protective layer and a second protective layer;
forming a second dielectric layer filling in the trench, wherein a top surface of the second dielectric layer is aligned with a top surface of the first protective layer; and
forming a first conductive via and a second conductive via, wherein the first conductive via penetrates the first protective layer and contacts the first SOT element, the second conductive via penetrates the second protective layer and contacts the second SOT element.

9. The fabricating method of an MRAM structure of claim 8, wherein the first memory structure comprises a first magnetic tunnel junction (MTJ), a third SOT element and a first conductive layer disposed from bottom to top and the second memory structure comprises a second MTJ, a fourth SOT element and a second conductive layer disposed from bottom to top.

10. The fabricating method of an MRAM structure of claim 8, wherein after forming the trench, the first SOT element and the first protective layer cover the first memory structure, the second SOT element and the second protective layer cover the second memory structure.

11. The fabricating method of an MRAM structure of claim 8, further comprising after forming the second dielectric layer, forming a third conductive via in the second dielectric layer and the third conductive via being disposed between the first memory structure and the second memory structure.

12. The fabricating method of an MRAM structure of claim 8, wherein the trench divides the spacer material layer into a first spacer and a second spacer, the first spacer is on the sidewall of the first memory structure, and the second spacer is on the sidewall of the second memory structure.

13. The fabricating method of an MRAM structure of claim 8, wherein a material of the second dielectric layer is different from a material of the first protective layer.
